(19) United States
(12) Patent Application Publication
(10) Pub. No.: US 2002/0000580 A1
(43) Pub. Date: Jan. 3, 2002

(54) SCALABLE MANUFACTURE PROCESS FOR POWER MOSFET WITH FULLY SELF-ALIGNED SHRINKABLE GATE AND DRAIN

(76) Inventors: KOICHI OKASHITA, CUPERTINO, CA (US); KOON CHONG SO, SAN JOSE, CA (US); SHANG-LIN WENG, CUPERTINO, CA (US); FWU-IUAN HSHIEH, SARATOGA, CA (US)

Correspondence Address: BO-IN LIN, 13445 MANDOLI DRIVE, LOS ALTOS HILLS, CA, 94022

(21) Appl. No.: 09/085,303

(22) Filed: May 27, 1998

Related U.S. Application Data
(60) Provisional application No. 60/074,093, filed on Feb. 9, 1998.

(51) Int. Cl. H01L 29/76

(52) U.S. Cl. 257/213

(57) ABSTRACT

This invention discloses a MOSFET power device supported on a substrate. The MOSFET power device includes a plurality metal-polysilicon gate segments disposed over a gate oxide layer and a plurality of source/drain metal segments each disposed over a corresponding drain or source region in the substrate. The MOSFET power device further includes a plurality of insulating oxide blocks each disposed between a corresponding gap between the source/drain metal segment and the metal-polysilicon gate segment Each of the metal-polysilicon gate segments includes a metal layer disposed above a polysilicon layer wherein a thickness T_{M} of the metal layer is greater than or equal to half of the width W_{G} of the metal-polysilicon gate, i.e., T_{M}≧0.5(W_{G}). And, each of the insulating oxide blocks having a thickness T_{O} greater than or equal to half of the width of the oxide block W_{O}, i.e., T_{O}≧0.5(W_{O}).

This Application is a Continuation-in-Part (CIP) Application of a prior Provisional Application No. 60/074,093 filed on Feb. 9, 1998.

### BACKGROUND OF THE INVENTION

1. Field of the Invention

This invention relates generally to the structure and fabrication process of MOSFET power devices. More particularly, this invention relates to a novel and improved MOSFET device structure and fabrication process. The MOSFET power device is made with total self-aligned and scalable processes such that the MOSFET power device with reduced transistor cell size can be manufactured with controllable and simplified processes while achieving very high precision in controlling the critical dimension of the transistor cell. Better performance with ultra-high speed and for ultra-high frequency operations and product reliability are also achieved because a metal-polysilicon interface structure with higher reliability is implemented.

2. Description of the Prior Art

The goal of manufacturing a highly efficient power MOSFET device suitable for fast-switching higher bandwidth applications with sub-micron transistor cells is hindered by several technical difficulties. Specifically, for high frequency application, conventional power MOSFET amplifiers has a problem of low efficiency at frequencies higher than 1 GHz. High on-state resistance, large output capacitance and low cutoff frequency cause the low efficiency of a conventional MOSFET device. A MOSFET device of short channel length is required for operation at high frequencies. However, misalignment tolerances often limit the reduction of the channel length.

In order to overcome the above problems, Yoshida et al. published two articles for a highly efficient 1.5 GHz silicon power MOSFET for digital cellular applications. (Proceeding of 1992 International Symposium on Power Semiconductor Devices & ICs, Tokyo pp 156-157, and Proceeding of 6th International Symposium on Power Semiconductor Devices & ICs, Davos, Switzerland 1994, pp 425-429). As that shown in FIG. 1, the power MOSFET device includes transistor cells with sub-micrometer channel under a metallic, e.g., molybdenum, gate of approximately 0.8 micrometers in width. An N⁻ offset region is formed between the channel and a self-aligned N⁺ region. The offset region has a width of approximately 1.2 micrometers. A N+ source region is formed opposite to the drain region over the channel region.

The MOSFET as that shown in FIG. 1 presents several difficulties in the fabrication processes. Specifically, it is difficult to form a metal gate, e.g., molybdenum, gate, on a gate-oxide. The quality of metal-oxide interface is difficult to control. The process is more costly and the reliability of such a structure would be a major concern. Degradation of performance caused by defective gate structure is an uncontrollable uncertainties due to the facts that there are less experience in forming a metal gate on an gate oxide and lack of sufficient data to assure that such a structure would sustain long term operation without layer interface degradations. Furthermore, the misalignment tolerance between the contact mask and the N+ regions also limits the size of the transistor cells. Due to these limitations, applying the transistor cell structure and manufacture method disclosed by Yoshida et al. cannot provide power device for ultra-high frequency operation.

Therefore, there is still a need in the art of power device fabrication, particularly for MOSFET design and fabrication, to provide a structure and fabrication process that would resolve these difficulties.

### SUMMARY OF THE PRESENT INVENTION

It is therefore an object of the present invention to provide a new power MOSFET fabrication process and a new device structure to enable those of ordinary skill in the art of MOSFET fabrication to overcome the aforementioned limitations and difficulties.

Specifically, it is an object of the present invention to provide an improved MOSFET structure to achieve simplified fabrication processes. The processes become totally self-aligned and scalable with high degree of dimension control such that the transistor cells with reduced cell-size can be manufactured with improved performance and reliability.

Another object of the present invention is to provide a novel MOSFET structure and fabrication process wherein the metal gate structure is improved by employing an intermediate polysilicon layer. The gate structure is formed with a polysilicon-silicon interface supports a polysilicon-metal interface such that the fabrication process can be well controlled to fabricate MOSFET power device with high degree of reliability at a reduced production cost.

Another object of the present invention is to provide a novel MOSFET structure and fabrication process wherein the self-aligned scalable manufacture processes employ reduced number of masks such that cost savings are achieved by simplified the fabrication processes.

Briefly, in a preferred embodiment, the present invention includes a method for fabricating a power MOSFET device supported on a P-type substrate. The method includes the steps of: (a) growing a gate oxide layer on the substrate and depositing a first polysilicon layer, an intermediate oxide and a second polysilicon layer over a top surface of the substrate forming a polysilicon-oxide-polysilicon (POP) layer structure; (b) applying a polysilicon mask for patterning a plurality of polysilicon-oxide-polysilicon (POP) stack segments with stack gap separating every two of the POP stack segments wherein the stack gap having a gap depth D and a gap width W, and D≧0.5W. In a preferred embodiment, the method further includes steps of: (c) performing a second conductivity-type implant to form a plurality of second conductivity-type source and drain regions in the substrate; (d) depositing a conformal oxide layer followed by carrying out a planarization etch for removing the conformal oxide layer from above the polysilicon-oxide-polysilicon stack segments leaving a oxide block insulating every two of the polysilicon-oxide-polysilicon stack segments; (e) performing a polysilicon etch to remove the second polysilicon layer above the intermediate oxide layer; (f) performing an oxide etch to remove the intermediate oxide layer above the first polysilicon layer; (g) applying a high concentration second conductivity-type implant blocking mask for carrying out a polysilicon etch for removing the first polysilicon layer from areas not covered by the blocking mask thus defining a plurality of oxide-block gaps between every two of the insulating oxide blocks wherein each of the oxide-block gaps having a depth D_{O} and a gap width W_{O}, and D_{O}≧0.5W_{O}. In yet another preferred embodiment, the method further includes steps of: (h) performing a high concentration second conductivity-type implant to form a plurality of offset regions of a second conductivity type; (i) performing a metalization process by depositing a metal layer over an entire surface followed by carrying out a planarization metal etch leaving the metal layer on top of the first polysilicon layer to form a plurality of metal-over-polysilicon gates and leaving the metal layer in each of the oxide-block gaps to form a plurality of source and drain electrodes with the insulating oxide blocks disposed between the metal-on-polysilicon gates and neighboring source electrodes and drain electrodes with the metal layer of the metal-on-polysilicon gates having a thickness T and a width W and T≧0.5W.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1 is cross sectional view of a prior art MOSFET device manufactured with a direct metal on silicon gate structure and a long N-offset region near the drain region.

FIGS. 2 is a cross-sectional view of a MOSFET power device of this invention;

FIGS. 3A to 3H are a series of cross sectional views for illustrating the manufacturing processes for making an improved MOSFET power device of FIG. 2;

FIG. 4 is a cross sectional view showing a gap with aspect ratio greater than or equal to 0.5 depositing with gap-filling layer;

FIG. 5 is a cross sectional view of another preferred embodiment of an improved MOSFET power device of this invention;

FIG. 6 is a cross sectional view of another preferred embodiment of an improvement MOSFET power device provided with more convenient metal contacts of this invention;

FIGS. 7A to 7K are a series of cross sectional views for illustrating the manufacturing processes for making an alternate MOSFET power device of this invention.

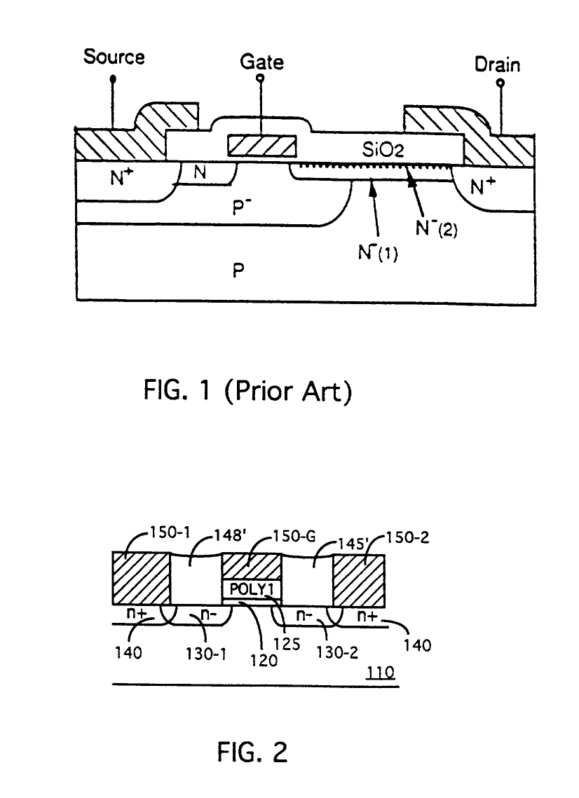

### DETAILED DESCRIPTION OF THE PREFERRED EMBODIMENT

Referring to FIG. 2 for a cross sectional view of a MOSFET power device 100 as a preferred embodiment of the present invention. The power MOSFET device 100 is supported on a P-type substrate 110. The power device 100 includes a first source/drain region 130-1 and a second source/drain region 130-2 disposed on two sides of a polysilicon-metal gate 125′ disposed over the top surface of the substrate 110. Since the power device is symmetrically bi-switch, either of the first and second source/drain regions can be a source or drain and the other source/drain region can then be employed in a complimentary manner. The polysilicon-metal gate 125′ is padded with a gate oxide layer 120 between the gate 125′ and the substrate 110. The polysilicon-metal gate includes a lower polysilicon layer 125 supporting a top metal layer 150-G, e.g., an aluminum gate-layer. In a different preferred embodiment, the metal layer 150-G can be a copper, a molybdenum layer or other types of conductive metal suitable for implementation as a gate metal.

The MOSFET power device 100 further includes a plurality of N⁺ offset regions 140 disposed next to the first source/drain regions 130-1 and the second source/drain regions 130-2 are farther away from the gate 125′. A source and drain metal segment is disposed above the offset regions 140 contacting the offset regions and the source and drain regions. Between the source/drain metal segments 150-1 and 150-2 and the polysilicon-metal gates 125′ is an insulating oxide block 145′. In one preferred embodiment, for the purpose of implementing a fully scalable manufacturing process-flow, each of the insulating oxide blocks 145′ has a thickness greater than or equal to half of the width of the block. And, each of the gate metal segments 150-G is also formed with the layer thickness greater than or equal to half of the width of the gate segment 150-G.

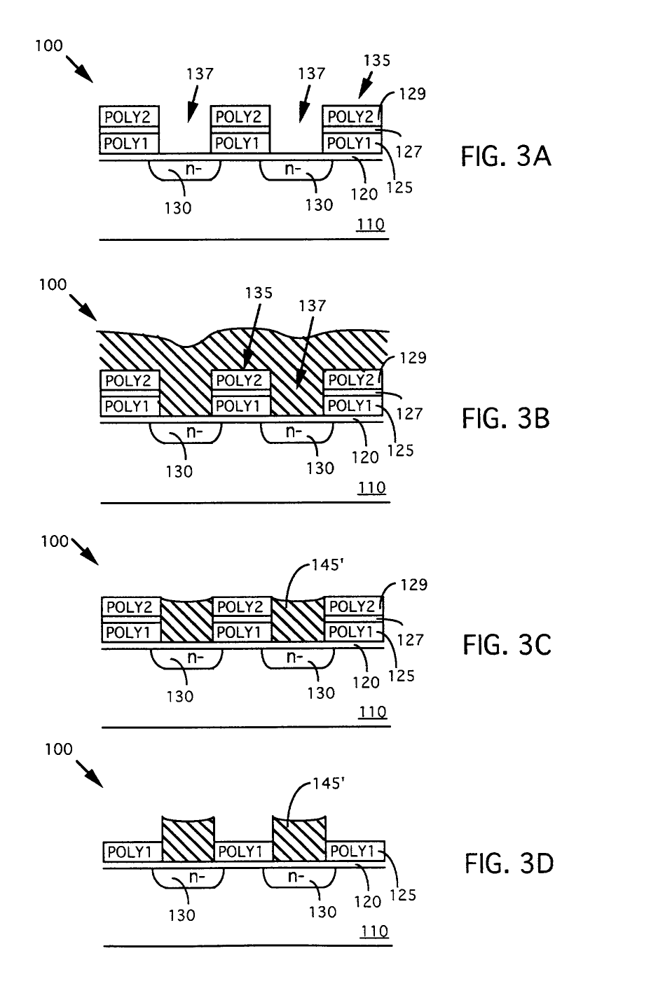

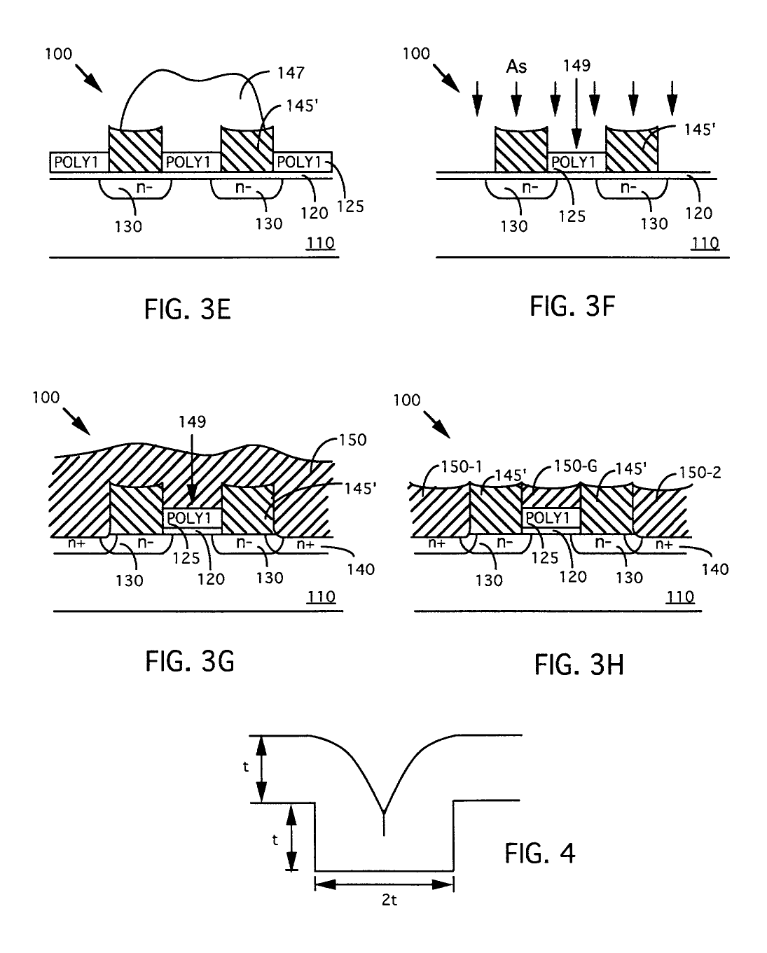

Referring to FIGS. 3A to 3G for the processing steps applied to manufacture the MOSFET device 100. As shown in FIG. 3A, the processing steps begins by first growing a gate oxide layer 120 on a P-type substrate 110. The gate oxide layer 120 having a thickness in the range of 100 to 1000 Angstroms. A first polysilicon layer 125, i.e., layer poly-1, having a thickness of approximately 2000 to 10,000 Angstroms is deposited on the top surface. A POCL₃ doping process is carried out Another thin oxide layer 127 having a thickness ranging from 100 to 3000 Angstroms is grown over the top surface. A second polysilicon layer 129, i.e., layer poly-2, having a thickness of approximately 2000 to 10,000 Angstroms is deposited over the top surface. A polysilicon doping process with POCL₃ is carried out The dopant concentration of the poly-2 129 is adjusted to control the etching rate of the poly-2 layer and the oxide layer 127. Polysilicon has a higher etching rate with high dopant concentration without changing the etching rate of the oxide layer. Selectivity of etching is improved to provide more process margins. In a alternate embodiment of this invention, this poly-2 layer can also a nitride layer. A nitride layer instead of the polysilicon layer as described above can also be implemented to achieve same advantages of structural and manufacture objectives.

A polysilicon mask is employed for etching and patterning the polysilicon-oxide-polysilicon (POP) layer structure into a plurality of polysilicon-oxide-polysilicon (POP) stacks segments 135. These POP stack segments 135 are formed with the gaps 137 between these POP stack segments. In one of the preferred embodiments, each of these gaps 137 has an aspect ratio greater than or equal to 0.5. Referring to FIG. 4 for an illustration of such a gap when the aspect ratio of the gap is about 0.5. In filling the gaps with a gap-filling material, a layer of approximately same thickness is also formed over the top of the POP stack segments because of the aspect ratio of these gaps. Thus the gaps 137 are patterned as deep and narrow gaps have an aspect ratio equal or greater than 0.5. The aspect ratio is defined as:

Gap Aspect Ratio=(Depth of Gap)/(Gap Lateral Width) (1)

For gaps 137:

Aspect Ratio of Gaps≧0.5 (2)

The gap width is about one to four micrometers and the depth of the gap is about three to five micrometers.

A N⁻ implant is carried out to form the N⁻ regions 130 with an ion beam of either phosphorus ions at an energy of 40-180 Kev and ion flux density of 1×10¹² to 1×10¹⁵/cm². Or, the N− implant is carried out by implanting arsenic ions at an energy of 40-180 Kev and ion flux density of 1×10¹² to 1×10¹⁵/cm². The N⁻ regions 130 are then driven to a depth of approximately 0.2 to 1.0 micrometers by applying an elevated temperature of 800 to 1000° C. for 10 minutes to 12 hours.

Referring to FIG. 3B, a conformal oxide layer 145, e.g., a spin-glass layer, is deposited. This conformal oxide layer 145 may be formed by several different methods such as TEOS, OX and SOG, BPSG, or TEOS and SOG processes. These oxide-layer processes are well known. No detail description would be required to those of ordinary skill in the art to perform each of these processes for carrying out the invention disclosed in this Patent Application. In FIG. 3C, a planarization oxide etch is performed by using either an end-point-detector or by controlling the etching time to remove the oxide layer 145 above the top surface of the polysilicon-oxide-polysilicon stacks segments 135. The planarization process can be carried out by applying a chemical mechanical planarization (CMP), a resist etch, SOG filling, or a BPSG flow process. These planarization processes are well known in the art and can be conveniently performed in the industry according to the disclosure made in this Patent Application.

In the preferred embodiment where the aspect ratio of the gaps 137 is greater than or equal to 0.5, the conformal oxide layer 145 filling the gaps 137 is not removed when the top surface layer is being etched away. For other types of embodiments, various equipment and techniques are available to keep the between-the-stack portion 145′ remaining the gaps. The remaining oxides kept in the gaps 137 thus constituting a plurality of insulating oxide blocks 145′. This configuration is achieved by either patterning the gaps 137 between the POP stack segments with an aspect ratio greater than or equal to 0.5 or applying other techniques readily available in the industry for integrated circuit fabrication. The insulating oxide blocks serves may useful functions as will be further described below.

Referring to FIG. 3D, a polysilicon etch is performed to remove the second polysilicon layer, e.g., poly-2 layer 129 or a nitride layer if nitride is formed instead of the polysilicon layer. An oxide-etch is then applied to remove the intermediate oxide layer 127. Special attentions are paid to applying an etching process that has high selectivity of oxide-etch without removing the polysilicon and without excessive lateral etching effects.

Referring to FIG. 3E, a N⁺ blocking mask 147 is applied for the purpose of forming the N⁺ regions 140. Because of the insulating oxide blocks 145′, the misalignment tolerance for placing of N+ blocking mask 147 is relaxed to almost as large as half of the width of the oxide blocks 145′. Referring to FIG. 3F, the poly-1 layer 125 that is not covered by the blocking mask 147 is etched and removed. A N+ implant is performed by implanting an ion beam of either phosphorus ions at an energy of 40-180 Kev and ion flux density of 1×10¹⁵ to 1×10¹⁶/cm² or arsenic ions at an energy of 40-180 Kev and ion flux density of 1×10¹⁵ to 1×10¹⁶/cm². The blocking mask 147 prevents the implanting ions from penetrating the polysilicon-1 layer 125. Thus there will be no implanting ions entering into the channel regions underneath the gate 125 as a result of the N+ implant. The N⁻ regions 140 are then driven to a depth of approximately 0.2 to 1.0 micrometer by applying an elevated temperature of 800-1000° C. for 10 minutes to 12 hours. The N+ blocking mask 147 is removed. A plurality of deep and narrow gaps 149 are thus formed between the insulating oxide blocks 145′.

Again, in one of a preferred embodiments, these gaps 149 are formed with an aspect ratio equal to or greater than 0.5. This is achieved by adjusting the total thickness H of the intermediate oxide layer 127 and the polysilicon-2 layer 129 to be greater than or equal to half of the width W of the poly-1 layer 125. Therefore for the gaps 149 a configuration is implemented with:

(H/W)≧0.5 (3)

Referring to FIG. 3G, a contact oxide etch is first performed to remove any residual oxide still left on the top surface of the silicon above the N⁺ regions 140. A metallization process is performed to deposit a metal layer 150 covering the entire top surface. This metal layer can be aluminum, copper, or other types of metal depending on specific design and application requirements. In the embodiment where the aspect ratio of the gaps 149 is greater than or equal to 0.5, the metal layer 150 is formed with almost a planar top surface as that shown in FIG. 3G.

Referring to FIG. 3H, a metal planarization etch process is carried out by using an end-point detector to remove the metal layer 150 above the top surface of the oxide blocks 145′. The metal planarization etch can also be perform by a time-etch. A plurality of metal segments are thus formed filling the gaps after the top surface layer is removed. The metal segment 150′ filling the gaps above the polysilicon layer 125 is a gate-metal segment 150-G. The metal layer left in the oxide block gaps 149 contacting the source regions 130-1 are the firs source/drain metal segments 150-1 and the metal layer left in the oxide-block gaps contact the drain regions 130-2 are the second source/drain metal segments 150-2.

A MOSFET power device 100 as described above is manufactured with only two masks, i.e., the polysilicon mask for defining the polysilicon-oxide-polysilicon stacks and a N region, and a N+ blocking mask for implanting the N+ offset regions 140. By employing these simplified manufacturing processes, the difficulties in manufacturing the prior art devices are resolved. Specifically, the metal gate structure required for high frequency application is now improved by placing a polysilicon-silicon interface underneath the gate metal segments 150-G. Much more reliable gate structure is provided which can accomplish a high speed switching to satisfy a high frequency requirement. Additionally, the widths of gate, source and drain are fully scalable. As the layout and configuration of the polysilicon mask is fixed, the width of the gate and the relative position and widths of the source and drain regions are automatically scaled. The processes for implanting and forming metal contact segments 150-G, 150-S and 150-D are fully self-aligned. The alignment requirement of applying the N+ blocking mask can be easily satisfied. Namely, the alignment requirement for applying the N+ blocking mask is to place the photo-resist to cover the polysilicon segments designed as gate-polysilicon. Since that segment is already surrounded by oxide blocks 145′, there is a very large misalignment tolerance, i.e., a tolerance as large as half of the width of the oxide blocks 145′. The manufacturing processes are therefore significantly simplified. Since the processes are self-aligned and fully scalable, the critical dimension of the power MOSFET device can be precisely controlled. A high quality low cost and high-density power MOSFET device can be conveniently manufactured with conventional CMOS process technologies suitable for high frequency applications.

According to FIGS. 2 to 4 and the above description, this invention discloses a MOSFET power device 100 supported on a substrate 110. The MOSFET power device includes a plurality metal-polysilicon gate segments 150-G disposed over a gate oxide layer 120 and a plurality of source-drain metal segments 150-1 or 150-2 each disposed over a corresponding drain or source region 130 in the substrate. The power MOSFET device further includes a plurality of insulating oxide blocks 145′ each disposed between a corresponding gap between the source-drain metal segment 150-1 or 150-2 and a metal-polysilicon gate segment 150-G. In one embodiment, the metal-polysilicon gate 150-G includes a gate layer disposed above a polysilicon layer 125 where the thickness of the metal layer is greater than or equal to half of the width of the metal-polysilicon gate 150-G. In one embodiment, each of the insulating oxide blocks 145′ also has a thickness greater than or equal to half of the width of the oxide block 145′. The MOSFET device 100 further include a plurality of offset regions disposed in the substrate near the source regions and the drain regions 130 underneath the source/drain metal segments 150-1 or 150-2. In a preferred embodiment, the substrate 110 of a first conductivity type is a P-type substrate and the source and drain regions of a second conductivity type are N-type regions. In a preferred embodiment, the offset regions 140 are high concentration N-type regions, i.e., N+ regions. In a preferred embodiment, the metal layer in the metal-polysilicon gate segments is a metal layer composed of aluminum. In an alternate preferred embodiment, the metal layer is a copper layer.

In summary, this invention further discloses a semiconductor substrate provided for supporting a power device thereon. The semiconductor substrate includes a gate oxide layer 120 covering the substrate. The substrate 110 further includes a plurality of polysilicon-oxide-polysilicon (POP) stack segments 135 disposed over the gate oxide layer. In a preferred embodiment, each of these POP stack segments 135 is separated from a neighboring segment by a gap 137. The gap 137 separating the neighboring POP stack segments 135 has an aspect ratio greater than or equal to 0.5.

According to FIGS. 3A to 4 and the above description, this invention discloses a method for fabricating a MOSFET device supported on a substrate 110 of a first conductivity type. The method includes the steps of (a) growing a gate oxide layer 120 on the substrate 110 and depositing a first polysilicon layer 125, an intermediate oxide 127 and a second polysilicon layer 129 over a top surface of the substrate 110 forming a polysilicon-oxide-polysilicon (POP) layer structure 135′; (b) applying a polysilicon mask for patterning a plurality of polysilicon-oxide-polysilicon (POP) stack segments 135 with stack gap 137 separating every two of the POP stack segments 135. In a preferred embodiment, the stack gap 137 having a gap depth D and a gap width W, and D≧0.5W. In a preferred embodiment, the method further includes steps of: (c) performing a second conductivity-type implant to form a plurality of second conductivity-type source and drain regions 130 in the substrate 110; (d)depositing a conformal oxide layer 145 followed by carrying out a planarization etch for removing the conformal oxide layer from above the polysilicon-oxide-polysilicon stack segments 135 leaving a oxide block 145′ insulating every two of the polysilicon-oxide-polysilicon stack segments 135; (e) performing a polysilicon etch to remove the second polysilicon layer 129 above the intermediate oxide layer 127; (f)performing an oxide etch to remove the intermediate oxide layer 127 above the first polysilicon layer 125; (g) applying a high concentration second conductivity-type implant blocking mask 147 for carrying out a polysilicon etch for removing the first polysilicon layer 125 from areas not covered by the blocking mask 147 thus defining a plurality of oxide-block gaps 149 between every two of the insulating oxide blocks 145′. In a preferred embodiment, each of the oxide-block gaps 149 having a depth D_{O} and a gap width W_{O}, and D_{O}≧0.5W_{O}. In another preferred embodiment, the method further includes steps of: (h) performing a high concentration second conductivity-type implant to form a plurality of offset regions 140 of a second conductivity type; (i) performing a metalization process by depositing a metal layer 150 over an entire surface followed by carrying out a planarization metal etch to form a plurality of metal-over-polysilicon gates 150-G and source/drain electrodes 150-1 or 150-2 with the insulating oxide blocks 145′ between the metal-on-polysilicon gates 150-G and a neighboring drain electrode 150-D and a neighboring source electrode 150-S. In a preferred embodiment, the metal layer 150′ of the metal-on-polysilicon gates 150-G having a thickness T and a width W and T≧0.5W.

In a preferred embodiment, the method is to fabricate the MOSFET device on a P-type substrate. In another preferred embodiment, the method is to fabricate the MOSFET device on a N-type substrate. In a preferred embodiment, the step (i) of depositing a metal layer 150 over an entire surface followed by carrying out a planarization metal etch to form a plurality of metal-over-polysilicon gates 150-G is a step of depositing an aluminum layer to form a plurality of aluminum-over-polysilicon gates. In an alternate preferred embodiment, the step (i) of depositing a metal layer over an entire surface followed by carrying out a planarization metal etch to form a plurality of metal-over-polysilicon gates 150-G is a step of depositing an copper layer to form a plurality of copper-over-polysilicon gates 150-G.

In yet another preferred embodiment, the step (i) of depositing a metal layer 150 over an entire surface followed by carrying out a planarization metal etch to form a plurality of metal-over-polysilicon gates is a step of depositing an molybdenum layer to form a plurality of molybdenum-over-polysilicon gates. In another preferred embodiment, the step (b) of applying a polysilicon mask for patterning a plurality of polysilicon-oxide-polysilicon (POP) stack segments 135 is a step of patterning the POP stack segments 135 with the stack gap 137 separating every two of the POP stack segments 135 with the gap width ranging from 0.2 to 1.5 micrometers and patterning the POP stack segment 135 with a segment width ranging from 0.2 to 1.5 micrometers.

In summary, this invention also discloses a method for fabricating a semiconductor power device supported on a substrate of a first conductivity type comprising steps of: (a) growing a gate insulation layer on the substrate 120 and depositing a first polysilicon layer 125, an intermediate oxide 127 and a second polysilicon layer 129 over a top surface of the substrate forming a polysilicon-oxide-polysilicon (POP) layer structure 135; (b) applying a polysilicon mask for patterning a plurality of polysilicon-oxide-polysilicon (POP) stack segments 135 with stack gap 137 separating every two of the POP stack segments 135. In a preferred embodiment, the stack gap 137 having a gap depth D and a gap width W, and D≧0.5W. In a preferred embodiment, the method further includes steps of (c) performing a second conductivity-type implant to form a plurality of second conductivity-type source and drain regions 130 in the substrate 110; (d) depositing a conformal oxide layer 145 followed by carrying out a planarization etch for removing the conformal oxide layer from above the polysilicon-oxide-polysilicon stack segments leaving a oxide block 145′ insulating every two of the polysilicon-oxide-polysilicon stack segments 135; (e) performing a polysilicon etch then an oxide etch to remove the second polysilicon layer 129 and the intermediate oxide layer 127; (f)applying a high concentration second conductivity-type implant blocking mask 147 for carrying out a polysilicon etch for removing the first polysilicon layer 125 from areas not covered by the blocking mask 147 thus defining a plurality of oxide-block gaps 149 between every two of the insulating oxide blocks 145′ wherein each of the oxide-block gaps having a depth D_{O} and a gap width W_{O}, and D_{O}≧0.5W_{O}. In a preferred embodiment, the method further includes steps of: (g) performing a high concentration second conductivity-type implant to form a plurality of offset regions 140 of a second conductivity type; (h) performing a metalization process by depositing a metal layer 150 over an entire surface followed by carrying out a planarization metal etch to form a plurality of metal-over-polysilicon gates 150-G and a plurality of source electrodes 150-1 and drain electrodes 150-2 with the insulating oxide blocks 145′ between the metal-on-polysilicon gates 150-G and neighboring source electrodes 150-1 and drain electrodes 150-2 wherein the metal layer 150′ of the metal-on-polysilicon gates 150-G having a thickness T and a width W and T≧0.5W.

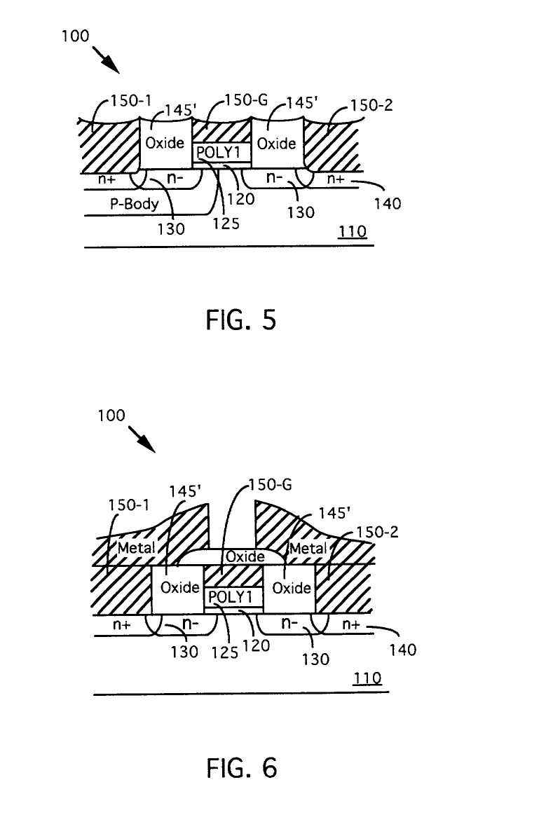

FIG. 5 shows a cross sectional view of an alternate preferred embodiment of this invention. A p-body is formed underneath the left-hand side of the source-drain regions. Employing a p-body mask to cover some of the gaps 137 designated for drain regions, i.e., the right-hand side gap 137 in FIG. 3A, a p-body implant is first performed. A p-body region is formed followed by a source implant to form the n+ source region. The p-body mask is then removed and a drain region N region implant is carried out to form the drain region 130-2. The p-body region provides the several benefits. Another degree of control is provided to flexibly adjust the device performance characteristics. Specifically, the threshold voltage, the early punch through prevention and other types of device characteristics can be conveniently adjusted by controlling the doping profile of this p-body region.

FIG. 6 is a cross section of another preferred embodiment of this invention. A passivation oxide layer is formed to cover the gate. A contact mask is then applied to open a plurality of contact openings includes source-drain contact openings and gate contact openings. A metal layer is then deposited and a metal mask is applied to pattern the metal layer into a plurality of metal segments. These metal segments include source-drain metal segments, gate metal segments and other necessary metal segments. Electric connections to the MOSFET device from other electronic devices can be more conveniently achieved by forming contacts to these source-drain, gate metal segments, and other metal segments when appropriate.

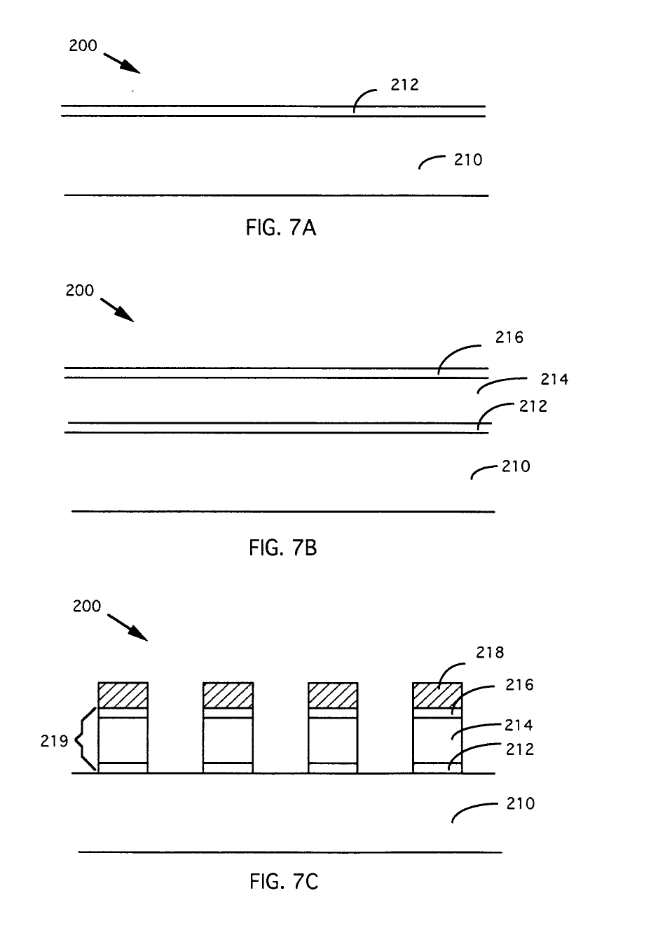

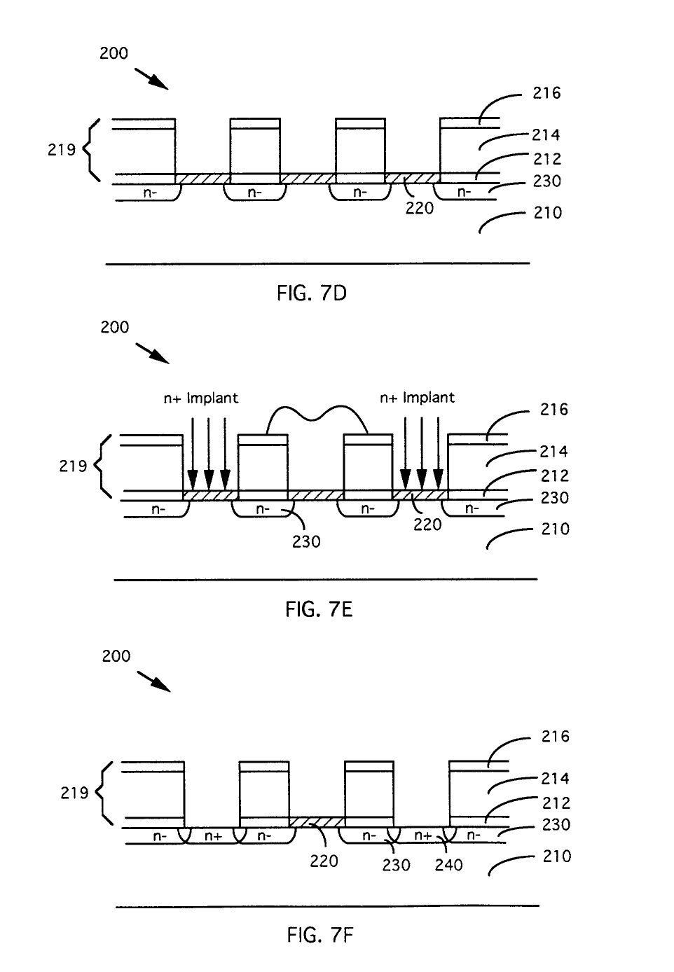

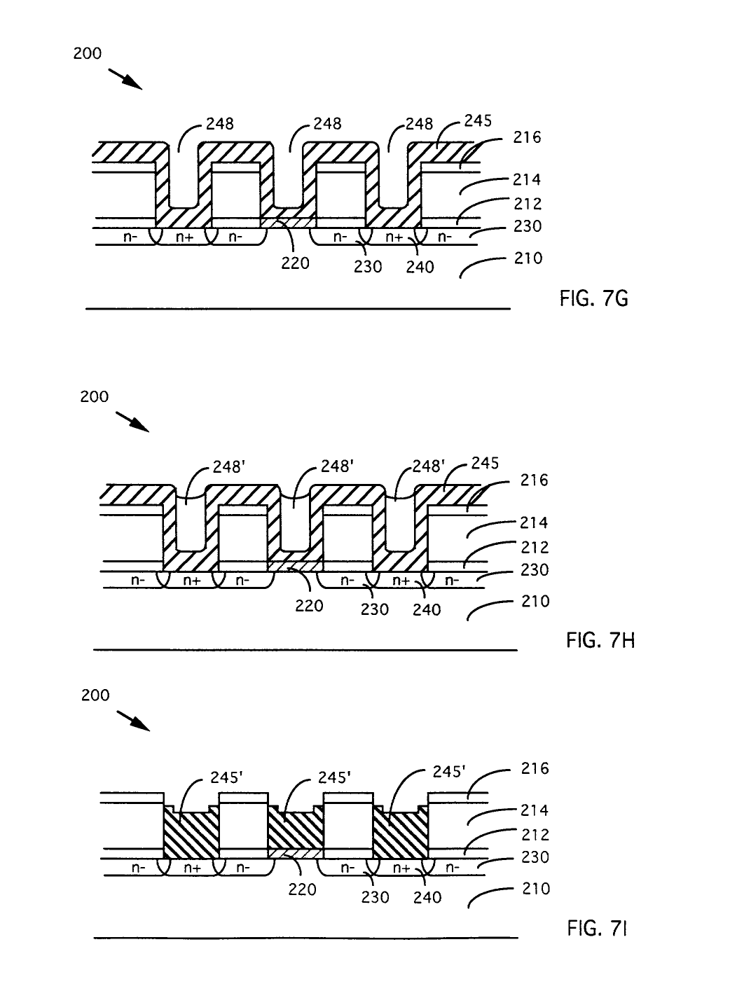

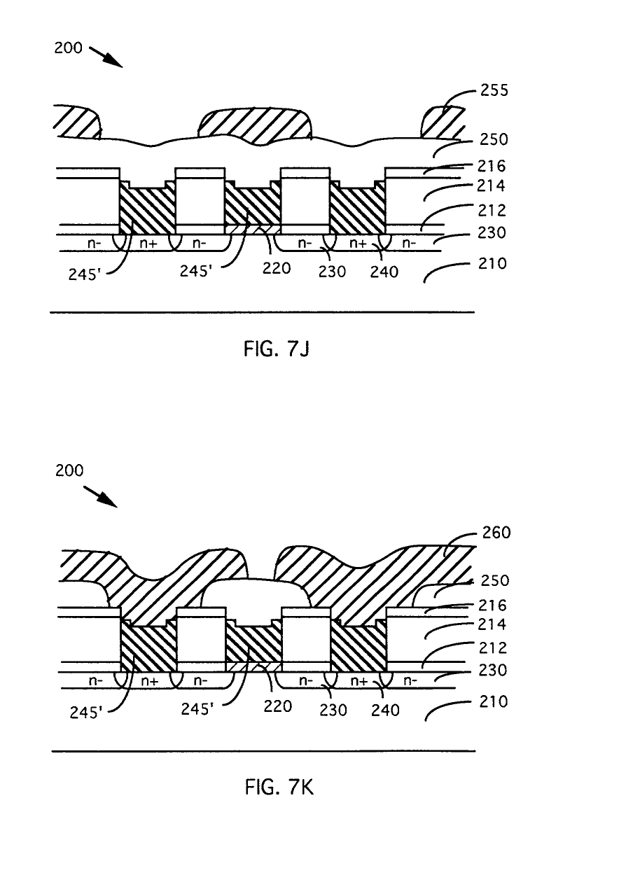

FIG. 7A to 7K are a series of cross sectional views to illustrate the fabrication processes employed for manufacturing another power MOSFET device 200 of this invention. As shown in FIG. 7A, the processing steps begins by first growing a first oxide layer 212 on a P-type substrate 210. The first oxide layer 212 having a thickness in the range of 1000 to 5000 Angstroms. A low energy n-type implant is performed to the first oxide layer with a low energy phosphorus or arsenic ion beams of 20-100 Kev. It is to be noted that the embodiment for illustration in this example is an n-channel MOSFET. The same manufacture processes can also be applied for a p-channel MOSFET. The polarity would then be reversed from the processes for the example described in FIGS. 7A to 7K.

Referring to FIG. 7B, a second oxide layer 214 and a nitride layer 216 are then formed at a low temperature covering the first oxide layer 212 implanted with n-type dopant ions. The second oxide layer 214 has a thickness of approximately 1000 to 10,000 Angstroms and the nitride layer 216 has a thickness ranging from 1000 to 5000 Angstroms. In FIG. 7C, a mask 218 is applied to etch the nitride layer 216, the second and the first oxide layers 214 and 212 into a plurality of nitride-oxide blocking segments 219.

Referring to FIG. 7D, a diffusion process is carried out by applying an elevated temperature of 800 to 1100° C. for 10 minutes to 12 hours. A plurality of source/drain N⁻ regions 230 are formed through the diffusion of the n-type dopant ions from the doped oxide layer 212 into the substrate 210. Meanwhile a gate oxide layer 220 is formed covering the substrate top surface between the nitride-oxide segments 119. The source/drain N− regions typically have a depth of 0.2-1.0 micrometer. Referring to FIG. 7E, a N+ blocking mask 222 is employed to cover the pre-designated gate spaces above the gate oxide layer 120. An N+ implant is performed by implanting an ion beam of either phosphorus ions at an energy of 40-180 Kev and ion flux density of 1×10¹⁵ to 1×10¹⁶/cm² or arsenic ions at an energy of 40-180 Kev and ion flux density of 1×10¹⁵ to 1×10¹⁶/cm². A plurality of N+ regions 240 are formed. Referring to FIG. 7F, the N+ blocking mask 222 is removed, and a high temperature cycle is applied at an elevated temperature of 800-1000° C. for 10 minutes to 3 hours to drive in the N+ regions 240 approximately 0.2 to 1.0 micrometer.

Referring to FIG. 7G, a metalization process is performed to form a conformal metal layer 245 covering the entire top surface with dips 248 between the nitride-oxide blocking segments 219. The metal layer 245 can be layer of aluminum, copper or other type of conductive materials. In FIG. 6H, a thin resist-spin 248′ is applied to fill the dips 248. The resist spin can be a spin-on-glass (SOG) material. Referring to FIG. 7I, a metal etch is performed to remove the top portion of the metal 245 from above the nitride-oxide blocking segments 219. The etch process for removing the top portion of the metal layer to form the gate 245′ is a self-aligned operation. Because the nitride layer 216 and the resist spin 248′ prevent the gate metal 245′ above the gate oxide layer 220 from being etched away.

Referring to FIG. 7J, an insulation layer of CVD oxide 250 is formed covering the entire top surface. A contact mask 255 is applied. In FIG. 7K the insulation 250 is etched to open the contacts, and a second metal layer 260 is formed. The top nitride layer 216 prevents the nitride oxide blocking segment 219 from being etched away during the contact etch process. The second metal layer 260 is further etched to form a plurality of metal segments such as gate metal and source metal segments to complete the manufacture process of the power MOSFET device 200.

According to FIGS. 7A to 7K and above description, this invention discloses a MOSFET power device supported on a substrate 210 of a first conductivity type. The device includes a plurality metal-gate segments 245′ disposed over a gate oxide layer 220 and a plurality of source/drain metal segments 245′ each disposed over a corresponding drain or source region 230 of a second conductivity in the substrate. The device further includes a plurality of insulating nitride-oxide blocking segments 219 each disposed between a corresponding gap between the source/drain metal segment 245′ and the metal-gate segment 245′. Each of the nitride-oxide blocking segments 219 includes a nitride layer 216 disposed above a second oxide layer 214, and the second oxide layer 214 disposed above a first oxide layer 212 disposed over a top surface of the substrate 210. In a preferred embodiment, the MOSFET device further includes a plurality of offset regions 240 disposed in the substrate 210. The offset regions 240 are near the source regions 230 and the drain regions 230 underneath the source/drain metal segments 245′ wherein the offset regions 230 having a higher dopant concentration of the second conductivity type. In a preferred embodiment, the substrate 210 of a first conductivity type is a P-type substrate and the source and drain regions 230 of a second conductivity type are N-type regions. In an alternate preferred embodiment, the substrate of a first conductivity type is an N-type substrate and the source and drain regions of a second conductivity type are P-type regions. In another preferred embodiment, the offset regions are high concentration N⁺ type regions. In an alternate preferred embodiment, the metal-gate segments 245′ are a metal layer composed of aluminum. In an alternate preferred embodiment, the metal-gate segments 245′ are a metal layer composed of copper. In Yet another preferred embodiment, the metal-gate segments are a metal layer composed of molybdenum.

According to FIGS. 7A to 7K, this invention discloses a method for fabricating a semiconductor power device supported on a substrate of a first conductivity-type. The method includes the steps of (a) forming a first insulation layer 212 on the substrate followed by implanting the first insulation layer 212 with ions of a second conductivity type; (b) forming a second insulation layer 214 on top of the first insulation layer 212 and an etch-resist insulation layer 216 on top of the second insulation layer 214; (c) applying a mask 218 for patterning the first insulation layer, the second insulation layer and the etch-resist insulation layer into a plurality of resist-insulation blocking segments 219; and (d) applying a diffusion temperature for growing a gate oxide layer 220 on a top surface of the substrate 210 between the resist-insulation blocking segments 219 and for diffusing the ions of the second conductivity in the first insulation layer to form source/ drain regions 230 of the second conductivity type in the substrate under the resist-insulation blocking segments 219. In a preferred embodiment, the step (c) of applying a mask 218 for patterning a plurality of resist-insulation blocking segments 219 is a step of patterning the resist-insulation blocking segments 219 separated by segment gaps having a gap depth D and a gap width W, and D≧0.5W. In another preferred embodiment, the step (b) of forming a second insulation layer 216 is a step of forming a silicon oxide layer on top of said first insulation layer 214, and said step of forming an etch-resist insulation layer 216 is a step of forming a silicon nitride layer on top of said second insulation layer 214.

Therefore, the present invention provides a new MOSFET fabrication process and a new device structure to enable those of ordinary skill in the art of MOSFET fabrication to overcome the limitations and difficulties of the prior art. Specifically, an improved MOSFET structure and fabrication process are disclosed with the fabrication processes simplified to become totally self-aligned and fully scalable with high degree of dimension control such that the transistor cells with reduced cell-size can be manufactured with improved performance and reliability. The MOSFET power device of this invention provides a metal-polysilicon gate structure with an intermediate polysilicon layer. The gate structure is formed with a polysilicon-silicon interface supports a polysilicon-metal interface such that the fabrication process can be well controlled to fabricate MOSFET power device with high degree of reliability at a reduced production cost This invention disclose a self-aligned scalable manufacture processes which employ reduced number of masks such that cost savings are achieved by simplified the fabrication processes.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A method for fabricating a MOSFET device supported on a substrate of a first conductivity type, comprising steps of:
(a) growing a gate oxide layer on said substrate and depositing a first polysilicon layer, an intermediate oxide and a second polysilicon layer over a top surface of said substrate forming a polysilicon-oxide-polysilicon (POP) layer structure;
(b) applying a polysilicon mask for patterning a plurality of polysilicon-oxide-polysilicon (POP) stack segments with stack gap separating every two of said POP stack segments wherein said stack gap having a gap depth D and a gap width W, and D≧0.5W.

2. The method for fabricating a MOSFET device of claim 1 further comprising steps of:
(c) performing a second conductivity-type implant to form a plurality of second conductivity-type source and drain regions in said substrate;
(d) depositing a conformal oxide layer followed by carrying out a planarization etch for removing said conformal oxide layer from above said polysilicon-oxide-polysilicon stack segments leaving a oxide block insulating every two of said polysilicon-oxide-polysilicon stack segments;
(e) performing a polysilicon etch to remove said second polysilicon layer above said intermediate oxide layer;
(f) performing an oxide etch to remove said intermediate oxide layer above said first polysilicon layer;
(g) applying a high concentration second conductivity-type implant blocking mask for carrying out a polysilicon etch for removing said first polysilicon layer from areas not covered by said blocking mask thus defining a plurality of oxide-block gaps between every two of said insulating oxide blocks wherein each of said oxide-block gaps having a depth D_{O} and a gap width W_{O}, and D_{O}≧0.5W_{O}.

3. The method for fabricating a MOSFET device of claim 2 further comprising steps of:
(h) performing a high concentration second conductivity-type implant to form a plurality of offset regions of a second conductivity type;
(i) performing a metalization process by depositing a metal layer over an entire surface followed by carrying out a planarization metal etch leaving said metal layer on top of said first polysilicon layer to form a plurality of metal-over-polysilicon gates and leaving said metal layer in each of said oxide-block gaps to form a plurality of source and drain electrodes with said insulating oxide blocks disposed between said metal-on-polysilicon gates and neighboring source electrodes and drain electrodes with said metal layer of said metal-on-polysilicon gates having a thickness T and a width W and T≧0.5W.

4. The method of fabricating said MOSFET device of claim 1 wherein:
said method is to fabricate said MOSFET device on a P-type substrate.

5. The method of fabricating said MOSFET device of claim 1 wherein:
said method is to fabricate said MOSFET device on a N-type substrate.

6. The method of fabricating said MOSFET device of claim 3 wherein:
said step (i) of depositing a metal layer over an entire surface followed by carrying out a planarization metal etch to form a plurality of metal-over-polysilicon gates is a step of depositing an aluminum layer to form a plurality of aluminum-over-polysilicon gates.

7. The method of fabricating said MOSFET device of claim 3 wherein:
said step (i) of depositing a metal layer over an entire surface followed by carrying out a planarization metal etch to form a plurality of metal-over-polysilicon gates is a step of depositing an copper layer to form a plurality of copper-over-polysilicon gates.

8. The method of fabricating said MOSFET device of claim 3 wherein:
said step (i) of depositing a metal layer over an entire surface followed by carrying out a planarization metal etch to form a plurality of metal-over-polysilicon gates is a step of depositing an molybdenum layer to form a plurality of molybdenum-over-polysilicon gates.

9. The method of fabricating said MOSFET device of claim 1 wherein:
said step (b) of applying a polysilicon mask for patterning a plurality of polysilicon-oxide-polysilicon (POP) stack segments is a step of patterning said POP stack segments with said stack gap separating every two of said POP stack segments with said gap width ranging from 0.2 to 1.5 micrometers and patterning said POP stack segment with a segment width ranging from 0.2 to 1.5 micrometers.

10. A method for fabricating a semiconductor power device supported on a substrate of a first conductivity type comprising steps of:
(a) growing a gate insulation layer on said substrate and depositing a first polysilicon layer, an intermediate oxide and a second polysilicon layer over a top surface of said substrate forming a polysilicon-oxide-polysilicon (POP) layer structure;
(b) applying a polysilicon mask for patterning a plurality of polysilicon-oxide-polysilicon (POP) stack segments with stack gap separating every two of said POP stack segments.

11. The method for fabricating the power device of claim 10 wherein:
said stack gap having a gap depth D and a gap width W, and D≧0.5W.

12. The method for fabricating the power device of claim 10 wherein:
said step of depositing a second polysilicon layer is a step of depositing a silicon nitride layer over said intermediate oxide layer thus forming a nitride-oxide-polysilicon (NOP) layer structure.

13. The method for fabricating the power device of claim 10 further comprising steps of:
(c) performing a second conductivity-type implant to form a plurality of second conductivity-type source and drain regions in said substrate;
(d) depositing a conformal oxide layer followed by carrying out a planarization etch for removing said conformal oxide layer from above said polysilicon-oxide-polysilicon stack segments leaving a oxide block insulating every two of said polysilicon-oxide-polysilicon stack segments;
(e) performing a polysilicon etch then an oxide etch to remove said second polysilicon layer and said intermediate oxide layer;
(f) applying a high concentration second conductivity-type implant blocking mask for carrying out a polysilicon etch for removing said first polysilicon layer from areas not covered by said blocking mask thus defining a plurality of oxide-block gaps between every two of said insulating oxide blocks.

14. The method for fabricating the power device of claim 13 further comprising steps of: wherein each of said oxide-block gaps having a depth D_{O} and a gap width W_{O}, and D_{O}≧0.5W_{O}.

15. The method for fabricating a power device of claim 13 further comprising steps of:
(g) performing a high concentration second conductivity-type implant to form a plurality of offset regions of a second conductivity type;
(h) performing a metalization process by depositing a metal layer over an entire surface followed by carrying out a planarization metal etch leaving said metal layer on top of said first polysilicon layer to form a plurality of metal-over-polysilicon gates and leaving said metal layer in each of said oxide-block gaps to form a plurality of source and drain electrodes with said insulating oxide blocks disposed between said metal-on-polysilicon gates and neighboring source and drain electrodes.

16. The method for fabricating the power device of claim 15 wherein:
said metal layer on said metal-on-polysilicon gates having a thickness T and said metal-on-polysilicon gates having a width W and T≧0.5W.

17. The method of fabricating said power device of claim 10 wherein:
said method is to fabricate said power device on a P-type substrate.

18. The method of fabricating said power device of claim 10 wherein:
said method is to fabricate said power device on a N-type substrate.

19. The method of fabricating said MOSFET device of claim 15 wherein:
said step (h) of depositing a metal layer over an entire surface followed by carrying out a planarization metal etch to form a plurality of metal-over-polysilicon gates is a step of depositing an aluminum layer to form a plurality of aluminum-over-polysilicon gates.

20. The method of fabricating said power device of claim 15 wherein:
said step (h) of depositing a metal layer over an entire surface followed by carrying out a planarization metal etch to form a plurality of metal-over-polysilicon gates is a step of depositing an copper layer to form a plurality of copper-over-polysilicon gates.

21. The method of fabricating said power device of claim 15 wherein:
said step (h) of depositing a metal layer over an entire surface followed by carrying out a planarization metal etch to form a plurality of metal-over-polysilicon gates is a step of depositing an molybdenum layer to form a plurality of molybdenum-over-polysilicon gates.

22. The method of fabricating said power device of claim 10 wherein:
said step (b) of applying a polysilicon mask for patterning a plurality of polysilicon-oxide-polysilicon (POP) stack segments is a step of patterning said POP stack segments with said stack gap separating every two of said POP stack segments with said gap width ranging from 0.2 to 1.5 micrometers and patterning said POP stack segment with a segment width ranging from 0.2 to 1.5 micrometers.

23. A MOSFET power device supported on a substrate of a first conductivity type comprising:
a plurality metal-polysilicon gate segments disposed over a gate oxide layer and a plurality of source/drain metal segments each disposed over a corresponding drain or source region in said substrate;
a plurality of insulating oxide blocks each disposed between a corresponding gap between said source/drain metal segment and said metal-polysilicon gate segment;
each of said metal-polysilicon gate segments includes a metal layer disposed above a polysilicon layer.

24. The MOSFET power device of claim 23 wherein:
a thickness T_{M} of said metal layer is greater than or equal to half of said width W_{G} of said metal-polysilicon gate, i.e., T_{M}≧0.5(W_{G}); and
each of said insulating oxide blocks having a thickness T_{O} greater than or equal to half of said width of said oxide block W_{O}, i.e., T_{O}≧0.5(W_{O}).

25. The MOSFET power device of claim 23 further comprising:
a plurality of offset regions disposed in said substrate near said source regions and said drain regions underneath said source/drain metal segments.

26. The MOSFET power device of claim 23 wherein:
said substrate of a first conductivity type is a P-type substrate and said source and drain regions of a second conductivity type are N-type regions.

27. The MOSFET power device of claim 23 wherein:
said substrate of a first conductivity type is a N-type substrate and said source and drain regions of a second conductivity type are P-type regions.

28. The MOSFET power device of claim 25 wherein:
said offset regions are high concentration N⁺ type regions.

29. The MOSFET power device of claim 23 wherein:
said metal layer in said metal-polysilicon gate segments is a metal layer composed of aluminum.

30. The MOSFET power device of claim 23 wherein:
said metal layer in said metal-polysilicon gate segments is a metal layer composed of copper.

31. The MOSFET power device of claim 23 wherein:
said metal layer in said metal-polysilicon gate segments is a metal layer composed of molybdenum.

32. A semiconductor substrate covered with a gate insulation layer for supporting a power device thereon comprising:
a plurality of dielectric-oxide-dielectric (DOD) stack segments disposed over said gate oxide layer wherein each of said DOD stack segments is separated from a neighboring segment.

33. The semiconductor substrate of claim 32 wherein:
each of said DOD stack segments is separated from a neighboring segment by a gap having an aspect ratio greater than or equal to 0.5.

34. A method for fabricating a MOSFET device supported on a substrate of a first conductivity type, comprising steps of:
(a) growing a first oxide layer on said substrate followed by implanting said first oxide layer with ions of a second conductivity type;
(b) forming a second oxide layer on top of said first oxide layer and a silicon nitride layer on top of said second oxide layer;
(c) applying a mask for patterning said first oxide layer, said second oxide layer and said silicon nitride layer into a plurality of nitride-oxide blocking segments; and
(d) applying a diffusion temperature for growing a gate oxide layer on a top surface of said substrate between said nitride-oxide blocking segments and for diffusing said ions of said second conductivity in said first oxide layer to form source/drain regions of said second conductivity type in said substrate under said nitride-oxide blocking segments.

35. The method for fabricating a MOSFET device of claim 34 further comprising steps of:
(c) applying an gate-contact mask for covering selected gaps between said nitride-oxide blocking segments followed by implanting a gate-contact regions of said second conductivity type between said source/drain region then removing said gate-contact mask;
(d) forming a conformal gate-metal layer having a valley between said nitride-oxide blocking segments followed by filling each of said valleys with a resist; and
(e) performing a metal etch for removing a top portion of said gate-metal layer above said nitride-oxide segment leaving said gate-metal layer filling a gap between said nitride-oxide blocking segments.

36. The method for fabricating a MOSFET device of claim 35 further comprising steps of:
(f) forming an insulating layer covering said MOSFET device followed by applying a contact mask for opening a plurality of contact openings through said insulating layer followed by depositing and patterning a second metal layer to form a plurality of gate and drain/source metal-segments.

37. The method of fabricating said MOSFET device of claim 34 wherein:
said method of fabricating said MOSFET device on a substrate of said first conductivity type is to form said device on said substrate of a P-conductivity type.

38. The method of fabricating said MOSFET device of claim 34 wherein:
said method of fabricating said MOSFET device on a substrate of said first conductivity type is to form said device on said substrate of a N-conductivity type.

39. The method of fabricating said MOSFET device of claim 36 wherein:
said step (d) of forming a conformal gate-metal layer is a step of depositing an aluminum layer to form a plurality of metallic gates of aluminum.

40. The method of fabricating said MOSFET device of claim 36 wherein:
said step (d) of forming a conformal gate-metal layer is a step of depositing an copper layer to form a plurality of metallic gates of copper.

41. The method of fabricating said MOSFET device of claim 36 wherein:
said step (d) of forming a conformal gate-metal layer is a step of depositing an molybdenum layer to form a plurality of metallic gates of molybdenum.

42. The method of fabricating said MOSFET device of claim 34 wherein:
said step (c) of applying a mask for patterning said first oxide layer, said second oxide layer and said silicon nitride layer into a plurality of nitride-oxide blocking segments is a step of forming said nitride-oxide blocking segments having a segment-width ranging from 0.2 to 1.5 micrometers and with gaps separating said nitride-oxide segments with a gap-width ranging from 0.2 to 1.5 micrometers.

43. A method for fabricating a semiconductor power device supported on a substrate of a first conductivity-type comprising steps of:
(a) forming a first insulation layer on said substrate followed by implanting said first insulation layer with ions of a second conductivity type;
(b) forming a second insulation layer on top of said first insulation layer and an etch-resist insulation layer on top of said second insulation layer;
(c) applying a mask for patterning said first insulation layer, said second insulation layer and said etch-resist insulation layer into a plurality of resist-insulation blocking segments; and
(d) applying a diffusion temperature for growing a gate oxide layer on a top surface of said substrate between said resist-insulation blocking segments and for diffusing said ions of said second conductivity in said first insulation layer to form source/drain regions of said second conductivity type in said substrate under said resist-insulation blocking segments.

44. The method for fabricating the power device of claim 43 wherein:
said (c) of applying a mask for patterning a plurality of resist-insulation blocking segments is a step of patterning said resist-insulation blocking segments separated by segment gaps having a gap depth D and a gap width W, and D≧0.5W.

45. The method for fabricating the power device of claim 43 wherein:
said step (b) of forming a second insulation layer is a step of forming a silicon oxide layer on top of said first insulation layer, and said step of forming an etch-resist insulation layer is a step of forming a silicon nitride layer on top of said second insulation layer.

46. A MOSFET power device supported on a substrate of a first conductivity type comprising:
a plurality metal-gate segments disposed over a gate oxide layer and a plurality of source/drain metal segments each disposed over a corresponding drain or source region of a second conductivity in said substrate;
a plurality of insulating nitride-oxide blocking each disposed between a corresponding gap between said source/drain metal segment and said metal-gate segment; and
each of said nitride-oxide blocking segments includes a nitride layer disposed above a second oxide layer, and said second oxide layer disposed above a first oxide layer disposed over a top surface of said substrate.

47. The MOSFET power device of claim 46 further comprising:
a plurality of offset regions disposed in said substrate near said source regions and said drain regions underneath said source/drain metal segments wherein said offset regions having a higher dopant concentration of said second conductivity type.

48. The MOSFET power device of claim 46 wherein:
said substrate of a first conductivity type is a P-type substrate and said source and drain regions of a second conductivity type are N-type regions.

49. The MOSFET power device of claim 46 wherein:
said substrate of a first conductivity type is a N-type substrate and said source and drain regions of a second conductivity type are P-type regions.

50. The MOSFET power device of claim 47 wherein:
said offset regions are high concentration N⁺ type regions.

51. The MOSFET power device of claim 46 wherein:
said metal-gate segments is a metal layer composed of aluminum.

52. The MOSFET power device of claim 46 wherein:
said metal-gate segments is a metal layer composed of copper.

53. The MOSFET power device of claim 46 wherein:
said metal-gate segments is a metal layer composed of molybdenum.
